(19) United States
(12) Patent Application Publication
(10) Pub. No.: US 2003/0127042 A1
(43) Pub. Date: Jul. 10, 2003

(54) Method of forming high quality waveguides by vapor-phase proton-exchange process with post-thermal annealing and reversed proton-exchange

(76) Inventors: Der-Hou Tsou, Long Tan (TW); Shang-Yi Wu, Chong-Li city (TW); Ming-Heng Chen, Yao-Yuan (TW); Ming-Hsien Chou, Holmdel, NJ (US)

Correspondence Address: GEORGE O. SAILE & ASSOCIATES, 28 DAVIS AVENUE, POUGHKEEPSIE, NY, 12603, US

(21) Appl. No.: 10/042,570

(22) Filed: Jan. 9, 2002

(51) Int. Cl. C30B 1/00

(52) U.S. Cl. 117/3

(57) ABSTRACT

A method of fabricating a waveguide in ferroelectric crystals, comprising the following steps. A ferroelectric crystal is provided. A vapor phase proton is diffused into the ferroelectric crystal by a vapor proton-exchange process to form a vapor proton-exchange (VPE) waveguide material structure having a step refractive index profile. The VPE waveguide material structure is treated with one or more processes selected from the group consisting of: a post thermal anneal process and an additional reverse proton-exchange process to complete fabrication of the waveguide, whereby the refractive index profile of the fabricated waveguide can be flexibly optimized. This method can form a high-quality waveguide and also provides a full degree of design flexibility for device optimization in several applications.

### FIELD OF THE INVENTION

The present invention relates generally to optical device fabrication and more specifically to methods of fabricating waveguides having engineerable refractive index profiles as well as preferred optical properties such as waveguide propagation loss, nonlinearity, electro-optical (EO), acusto-optical (AO) and uniformity, for example.

### BACKGROUND OF THE INVENTION

A vapor phase proton exchange (VPE) process can be used to form a preferred homogeneous crystal phase in several ferroelectric crystals such as lithium niobate (LiNbO₃) and lithium tantalate (LiTaO₃). Important optical properties, such as electro-optical (EO), acusto-optical (AO) and nonlinear optical properties can be preserved by VPE processing as compared to the observed degradation in these properties when other liquid-phase proton exchange processes are used.

The superior optical properties with lower waveguide propagation loss and higher nonlinearity are well suited for several applications. As an example, FIGS. 1(a)-(g) illustrate the crystalline phase of different processes resolved by X-ray rocking curve measurements in the prior art. That is:

(a) APE (Annealed proton-exchange) waveguide: peak shift at 162 second (alpha phase);

(b) PE (proton exchange via liquid phase) waveguide: peak shift 594 second (beta phase);

(c) waveguide of VPE for 8 hours at 300° C.: peak shift 504 second (kappa phase);

(d) waveguide of VPE for 10 hours at 300° C.: peak shift 504 second (kappa phase);

(e) waveguide of VPE 12 hours at 300° C.: peak shift 504 second (kappa phase);

(f) waveguide of VPE 20 hours at 300° C.: peak shift 504 second (kappa phase); and

(g) waveguide of VPE 30 hours at 300° C.: peak shift 504 second (kappa phase).

The alpha and kappa phase in general exhibit superior optical properties, as compared to beta phase. However, as compared to alpha phase, the kappa phase has a higher index profile, which is preferred in several waveguide applications. FIGS. 1(c) through (g) show the peak shift of 504 second, which reveals the kappa phase of those samples. A kappa structure has shown to exist with a maximum depth below 5 μm under the example process condition. For deeper depth, it can also be achieved via careful control of vapor phase process, such as temperature, time, and acid concentration.”

However, waveguides formed by conventional VPE processes in general form a step-like index profile with a high refractive index jump as shown in FIGS. 2 and 3, respectively. In FIGS. 2 and 3:

(a) APE (annealed proton-exchange) waveguide;

(b) PE (proton exchange via liquid phase) waveguide for 36 hours duration at 160° C.;

(c) waveguide for VPE for 8 hours duration at 300° C.;

(d) waveguide for VPE for 10 hours duration at 300° C.;

(e) waveguide for VPE for 12 hours duration at 300° C.;

(f) waveguide for VPE for 20 hours duration at 300° C.; and

(g) waveguide for VPE for 30 hours duration at 300° C.

As shown in FIGS. 2 and 3, the VPE process yields high index profile waveguides (samples c, d, e, f and g) as compared to APE process waveguides (sample a—alpha phase structure with Δnₑ<0.03). Although PE waveguide (sample b) can have a higher index profile as compared to VPE process waveguide, the sample prepared by PE process in general results in degraded optical properties. Thus VPE processes permits fabrication of tightly confined waveguides which benefits the efficiency in waveguide nonlinear frequency conversion. The kappa (κ) phase (samples c to g) can be achieved for different depths as long as the process can be performed at an optimized fabrication condition. This property allows one to design and fabricate VPE waveguides for a variety of applications.

However, such single step VPE process waveguides of FIGS. 2 and 3 can not necessarily generate optimized designs for applications.

The J. Rams et al. article entitled “Nonlinear optical efficient LiNbO₃ waveguides proton exchanged in benzoic acid vapor: Effect of the vapor pressure,” Journal of Applied Physics, Vol. 85, No. 3, p.p. 1322 to 1328 (1 Feb. 1999) describes the effect of the vapor pressure on the properties of LiNbO₃ waveguides proton-exchanged in benzoic acid vapor.

The J. Rams et al. article entitled “Preparation of proton-exchange LiNbO₃ waveguides in benzoic acid vapor,” J. Opt. Soc. Am. B, Vol. 16, No. 3, p.p. 401 to 406 (March 1999) describes formation of alpha- or beta-phase LiNbO₃ waveguides by proton-exchange of x- and z-cut substrates in benzoic acid vapor.

The M. L. Bortz et al. article entitled “Depth profiling of the d₃₃ nonlinear coefficient in annealed proton exchanged LiNbO₃ waveguides,” Appl. Phys. Lett., Vol. 62, No. 17, p.p. 2012 to 2014 (26 Apr. 1993) describes depth profiling of the d₃₃ nonlinear coefficient in annealed proton-exchanged LiNbO₃ waveguides using reflected second-harmonic generation from angle-lapped samples.

The Yu N. Korkishko et al. article entitled “Reverse proton exchange for buried waveguides in LiNbO₃,” J. Opt. Soc. Am. A, Vol. 15, No. 7, p.p. 1938 to 1842 (1998) describes a reverse proton-exchange (RPE) process performed in different HₓLi₁₋ₓNbO₃ crystalline phases of proton-exchanged and annealed proton-exchanged LiNbO₃ waveguides.

The J. L. Jackel et al. article entitled “Reverse Exchange Method For Burying Proton Exchanged Waveguides,” Electronics Letters, Vol. 27, No. 15, p.p. 1360 and 1361 (19 Jul. 1991) describes formation of buried proton-exchanged LiNbO₃waveguides. Following initial exchange and annealing steps which define the waveguides, a second exchange reintroduces lithium to lower the extraordinary refractive index at the surface.

The Ming-Hsin Chou (a co-inventor of the instant invention) dissertation entitled “Optical Frequency Mixers Using Three-Wave Mixing For Optical Fiber Communications” submitted to the Department of Applied Physics and the Committee on Graduate Studies of Stanford University in partial fulfillment of the requirements for the degree of Doctor of Philosophy (August 1999) describes the development of optical frequency (OF) mixers fabricated in periodically poled LiNbO₃ (PPLN) waveguides for optical fiber communications and other all-optical signal processing applications.

U.S. Pat. No. 5,521,750 to Onoe et al. describes a process for forming proton-exchange layer and wavelength converting element.

U.S. Pat. No. 4,948,407 to Bindell et al. describes a proton-exchange method of forming waveguides in LiNbO₃.

U.S. Pat. No. 5,734,494 to Xu et al. describes a wavelength conversion device and wavelength conversion method.

U.S. Pat. No. 5,838,486 to Sonoda et al. describes an optical wavelength conversion element, a method of manufacturing the same, and an optical wavelength conversion module.

U.S. Pat. No. 5,991,490 to Mizuuchi et al. describes an optical waveguide and optical wavelength conversion device.

U.S. Pat. No. 5,872,884 to Mizuuchi et al. describes an optical waveguide conversion device.

U.S. Pat. No. 6,002,515 to Mizuuchi et al. describes a method for producing a polarization inversion part, an optical wavelength conversion element using the same, and an optical waveguide.

U.S. Pat. No. 5,943,465 to Kawaguchi et al. describes an optical waveguide element, an optical element, a method for producing an optical waveguide element and a method for producing periodic domain-inverted structure.

U.S. Pat. No. 5,761,226 to Gupta describes frequency conversion laser devices.

U.S. Pat. No. 5,652,674 to Mizuuchi et al. describes a method for manufacturing domain-inverted regions, optical wavelength conversion devices utilizing such domain-inverted regions and a method for fabricating such a device.

U.S. Pat. No. 5,875,053 to Webjorn et al. describes periodic electric field poled crystal waveguides.

U.S. Pat. No. 5,434,700 to Yoo describes an all-optical wavelength converter.

U.S. Pat. No. 5,317,666 to Agostinelli et al. describes a waveguide nonlinear optical frequency converter with integral modulation and optimization means.

U.S. Pat. No. 4,925,263 to Sanford et al. describes proton-exchanged waveguides for sum-frequency generation.

U.S. Pat. No. 5,380,410 to Sawaki et al. describes a process for fabricating an optical device for generating a second harmonic optical beam.

U.S. Pat. No. 5,249,191 to Sawaki et al. describes a waveguide type second-harmonic generation element and method of producing the same.

U.S. Pat. No. 5,155,791 to Hsiung describes hybrid optical waveguides for phase-matched nonlinear wavelength conversion.

### SUMMARY OF THE INVENTION

Accordingly, it is an object of one or more embodiments of the present invention to provide an improved method of forming waveguides.

It is another object of one or more embodiments of the present invention to provide an improved method to engineer the device geometry with preferred optical properties for performance optimization.

Other objects will appear hereinafter.

It has now been discovered that the above and other objects of the present invention may be accomplished in the following manner. Specifically, a ferroelectric crystal is provided. A vapor phase proton is diffused into the ferroelectric crystal by a vapor proton-exchange process to form a vapor proton-exchange (VPE) waveguide material structure having a step refractive index profile. The VPE waveguide material structure is treated with one or more processes selected from the group consisting of: a post thermal anneal process and an additional reverse proton-exchange process to complete fabrication of the waveguide, whereby the refractive index profile of the fabricated waveguide is smoothed as compared to the step refractive index profile of the VPE waveguide material structure. The method described in this invention will allow fabrication of high quality waveguides with preferred optical properties and also allow design of refractive index profile for device performance optimization. For example, one will be able to design the preferred waveguide geometry by using the fabrication method described in this invention, which open up several design dimensions in achieving optimal device performance for a wide variety of applications.

### BRIEF DESCRIPTION OF THE DRAWINGS

The present invention will be more clearly understood from the following description taken in conjunction with the accompanying drawings in which like reference numerals designate similar or corresponding elements, regions and portions and in which:

FIGS. 1(a) through (g) are a series of graphs illustrating x-ray rocking curves for prior art samples ‘a’ through ‘g’ formed waveguide.

FIG. 2 is a table illustrating the refractive index change/refractive index jump for prior art samples “a” through “f” formed waveguides.

FIG. 3 is a graph illustrating index profiles for the prior art samples “a” through “f” formed waveguides of FIG. 2.

FIGS. 4 to 7 schematically illustrate preferred embodiments of the present invention.

FIGS. 8a through f schematically illustrate the resultant physical embodiments of the channel waveguides formed by the processes illustrated in FIGS. 4 to 7 as described herein.

FIGS. 9a and 9b schematically illustrate another example applications of the present invention.

FIGS. 10a through g schematically illustrates modified processes described in this invention to form a multi-layer waveguide geometry.

FIGS. 11a and 11b schematically represent physical embodiments of modified processes described in this invention to form a multi-layer waveguide geometry.

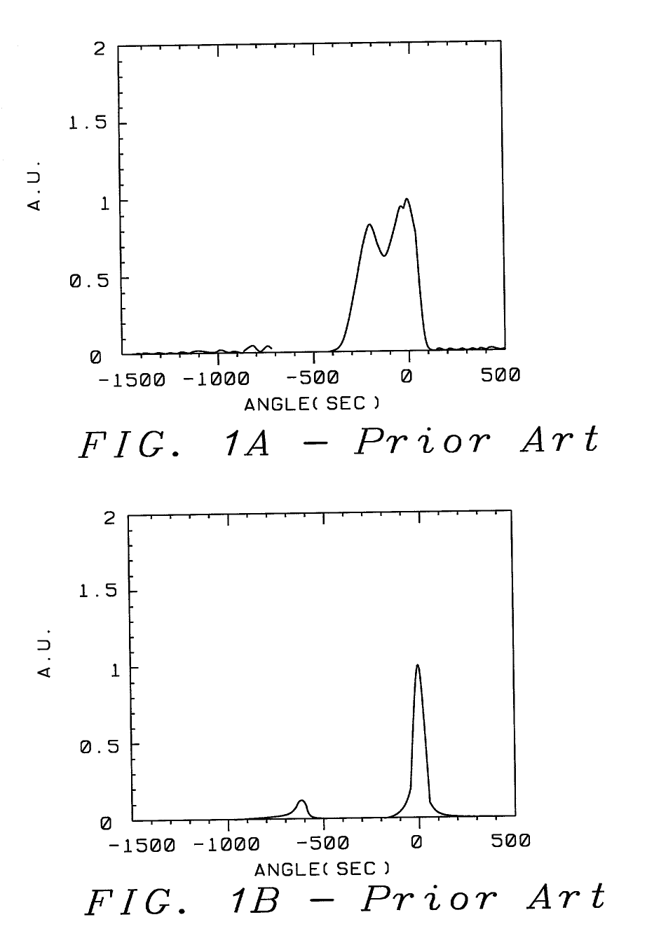

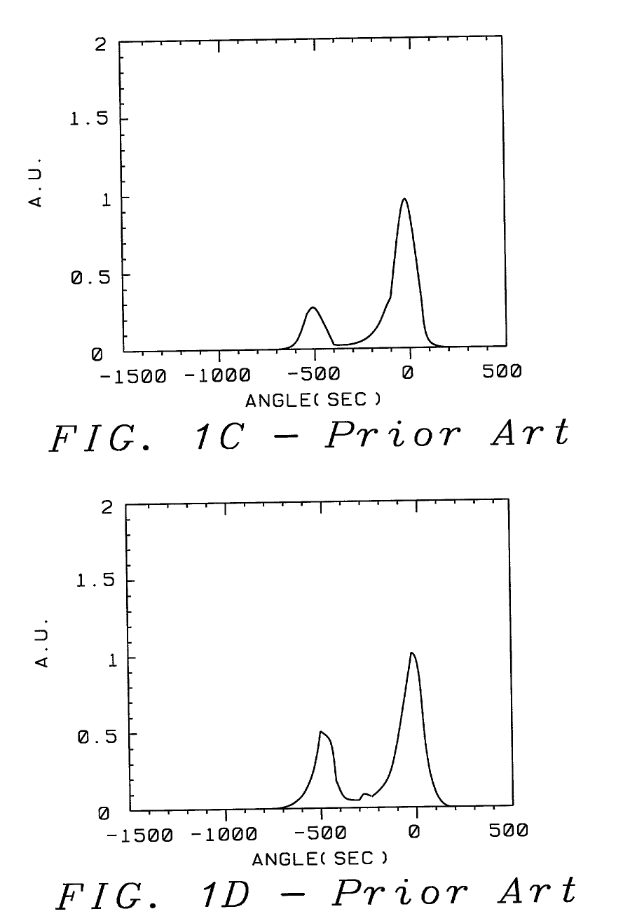

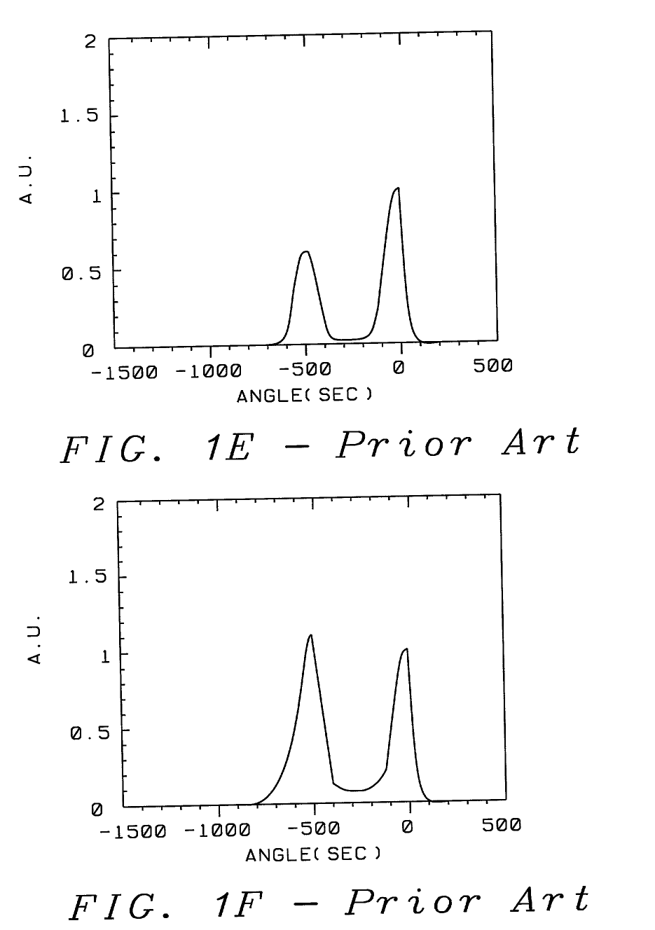

### DETAILED DESCRIPTION OF THE PREFERRED EMBODIMENT

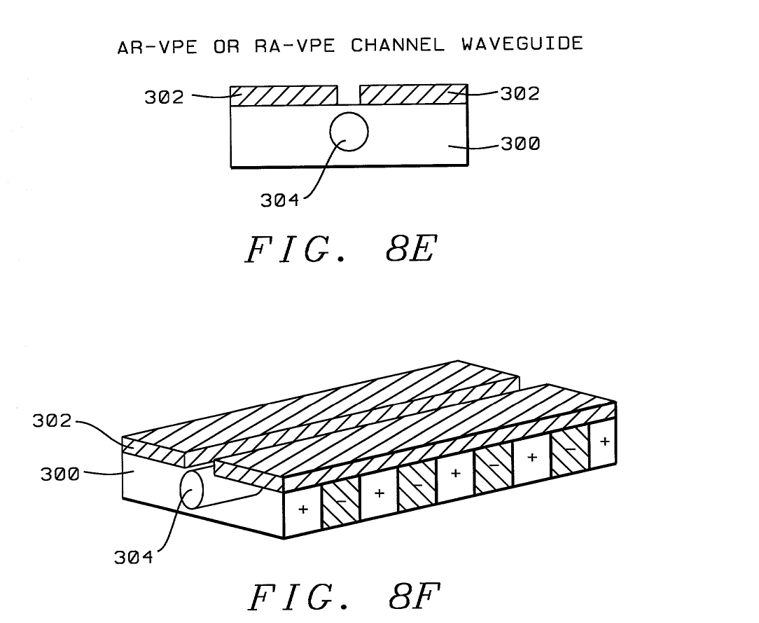

As shown in FIGS. 8a-f (with FIG. 8a a cross-sectional representation of FIG. 8b; FIG. 8c a cross-sectional representation of FIG. 8d; and FIG. 8e a cross-sectional representation of FIG. 8f), the processes described in this invention may be used to form high performance channel waveguides in the substrate with poled microstructures. Such type of devices has wide applications for nonlinear frequency conversion and optical frequency mixing.

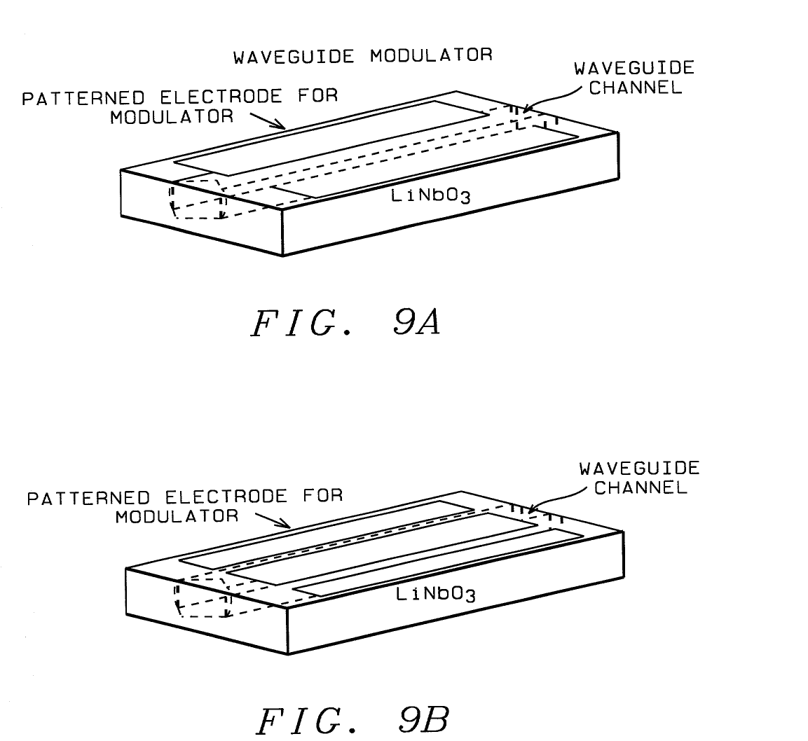

FIGS. 9a and 9b schematically illustrate other example applications of the present invention. Patterned electrodes at the sides of waveguides (FIG. 9a) and directly on top of waveguides (FIG. 9b) are shown as examples.

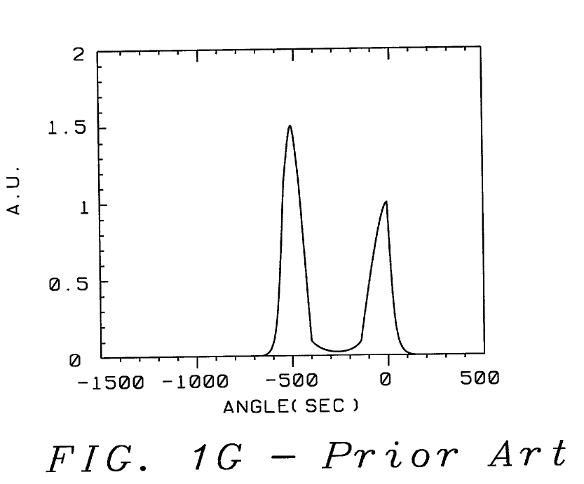

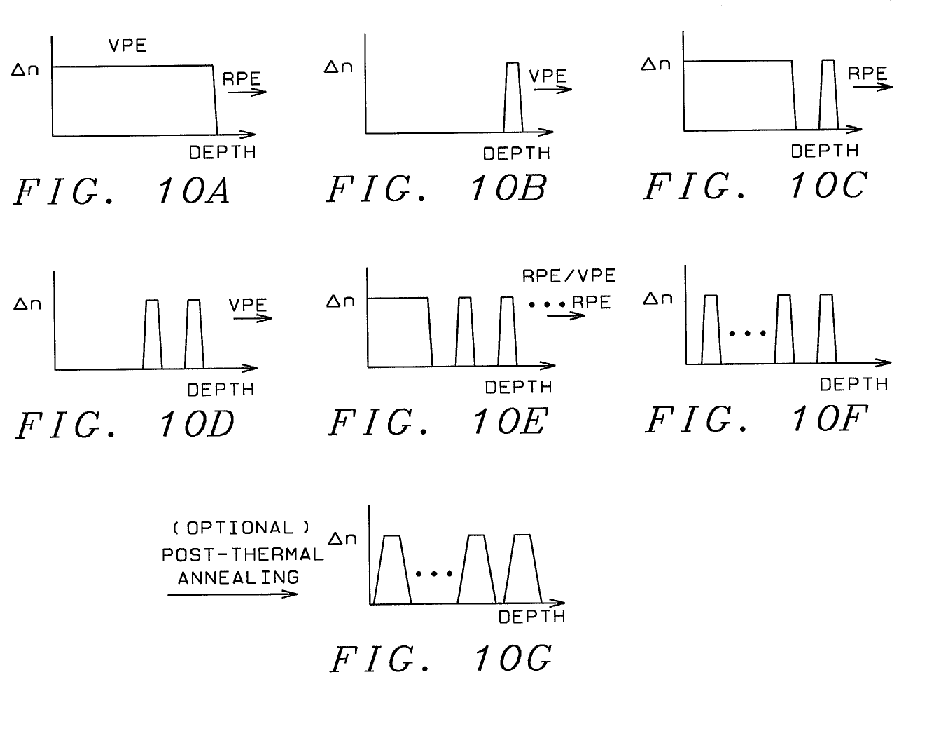

FIGS. 10a-g schematically illustrates the modified processes described in this invention (by combining the processes of the four embodiment processes illustrated in FIGS. 4 through 7) to form a multi-layer waveguide geometry. Such a structure has application for dispersion shifting, dispersion flattening, or efficiency enhancement.

Description of FIGS. 10a through 10g:

a. FIG. 10a: VPE process is performed on substrate to form an initial index profile.

b. FIG. 10b: Subsequent RPE process is performed to form a deep buried waveguide profile as a first sub-layer.

c. FIG. 10c: Subsequent VPE process is performed to form another sub-layer of waveguide profile.

d. FIG. 10d: Subsequent RPE process is performed to form another sub-layer of waveguide profile.

e. FIG. 10e: Subsequent VPE process is performed to form another sub-layer of waveguide profile.

f. FIG. 10f: Subsequent RPE process is performed to form another sub-layer of waveguide profile

g. FIG. 10g: (Optional) post thermal annealing can be performed to form the final profile of multi-layer waveguide structure.

Basically, FIGS. 10a through 10g illustrate an example of combining the process of the four embodiment processes illustrated in FIGS. 4 through 7. The example of FIGS. 10a-g show the extension of processes illustrated in FIGS. 4 through 7 by using a series of the processes, i.e. RPE/VPE/RPE/VPE . . . RPE/VPE, to form a more complex multi-layer waveguide.

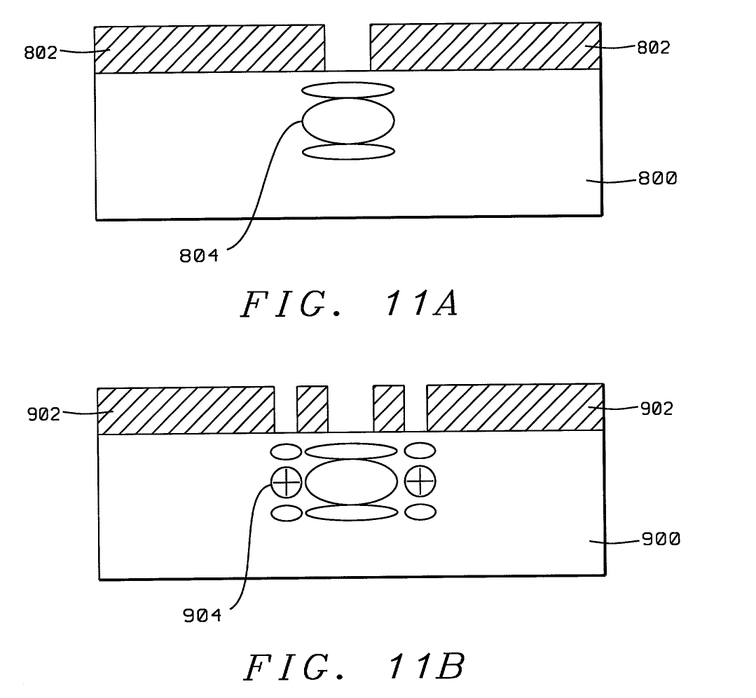

FIGS. 11a and 11b represent physical embodiments of waveguides fabricated by using a series of the processes illustrated in FIGS. 4 through 7. FIG. 11a illustrates a waveguide 804 formed within a substrate 800 (formed of LiNbO₃, for example) with an overlying channel waveguide mask 802 (formed of SiO₂, for example). FIG. 11b illustrates another waveguide 904 formed within a substrate 900 (formed of LiNbO₃, for example) with an overlying channel waveguide mask 902 (formed of SiO₂, for example).

The processes of the present invention consist of fabricating waveguides using vapor phase proton-exchange (VPE) followed by a post-thermal annealing treatment and/or a reversed proton-exchange process in ferroelectric materials/crystals such as lithium niobate (LiNbO₃), lithium tantalate (LiTaO₃), KTiOPO₄ (KTP), KNbO3 or KDP and their family such as MgO:LiNbO₃, ZnO:LiNbO₃, periodically poled KTP (PP-KTP) periodically poled lithium niobate (PP-LN) or periodically poled lithium tantalate (PP-LT) at different crystal orientations, i.e. X-cut, Y-cut or Z-cut. The more preferred ferroelectric materials/crystal is LiNbO₃ or LiTaO₃ and their family and the most preferred ferroelectric materials/crystal is LiNbO₃ and its family.

More specifically, the LiNbO₃ and their family include crystal at different formats such as congruent LiNbO₃ (CLN) and stoichiometric LiNbO₃ (SLN); above crystals with doping such as MgO:CLN, ZnO:CLN, MgO:SLN, ZnO:SLN; above crystals at different crystal orientations .i.e. . X-cut, Y-cut or Z-cut; and above crystals with periodic or a periodic ferroelectric domain reversals in their crystal bodies.

FIGS. 4 to 7 illustrate the one dimensional refractive indices in the depth direction of the preferred alternate embodiment waveguides of the present invention as the respective waveguides are formed.

As the preferred applications are used in the form of two dimensional channel waveguide structures, one should know that FIGS. 4 to 7 only illustrate the cross-section in the depth direction of two dimensional channel waveguides. The actual two dimensional index profiles will depend on the width of waveguide channels, which are in general defined through the predefined waveguide channel mask before the processes described in this invention.

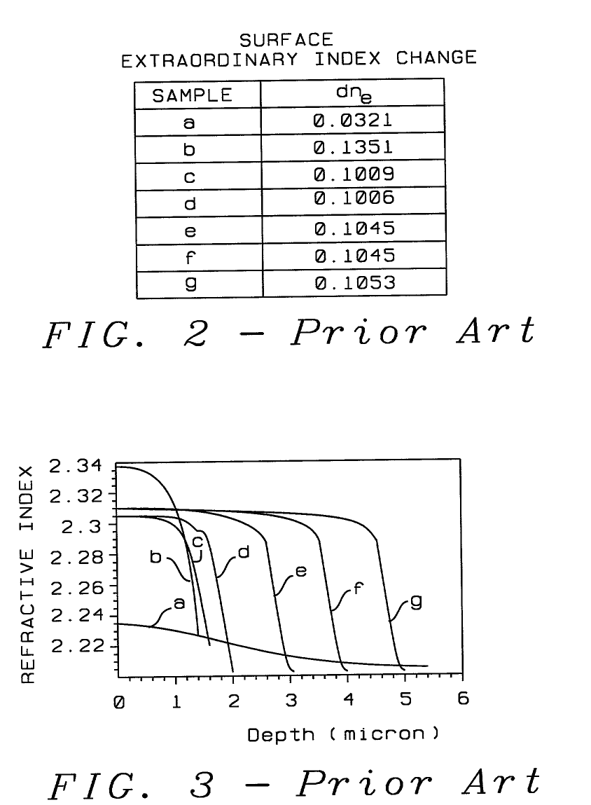

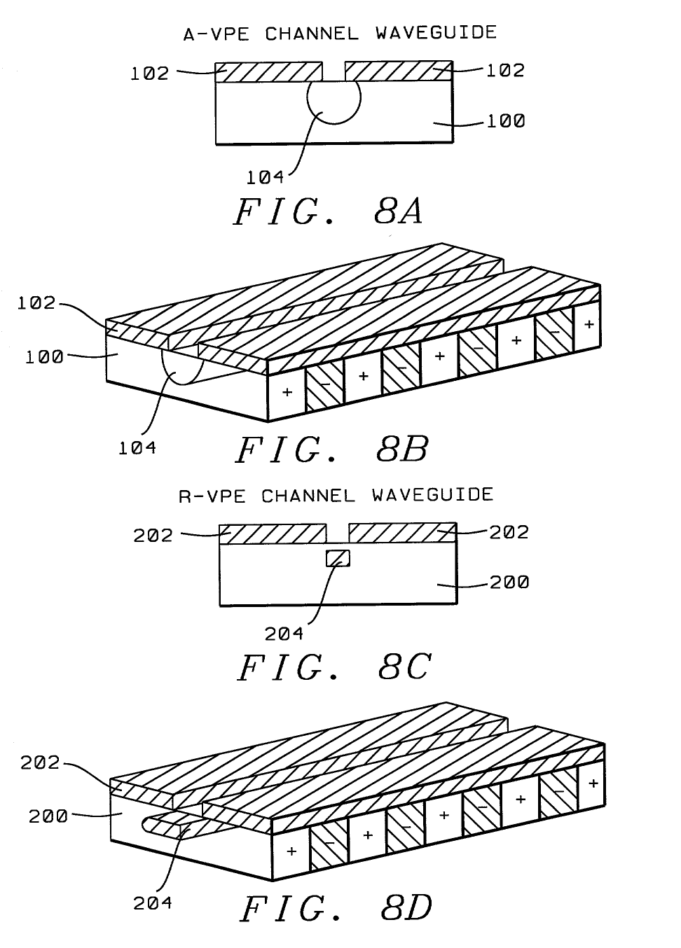

Those processes (as shown in FIGS. 4 through 7) are compatible with each other as they offer different design and process flexibility to each other. The RA-VPE (VPE+annealing+RPE) (as shown in FIG. 5) and AR-VPE (VPE+RPE+Annealing) (as shown in FIG. 7) are the most generic and more preferred methods as they offers maximum degree of freedoms in process for device deign and optimization.

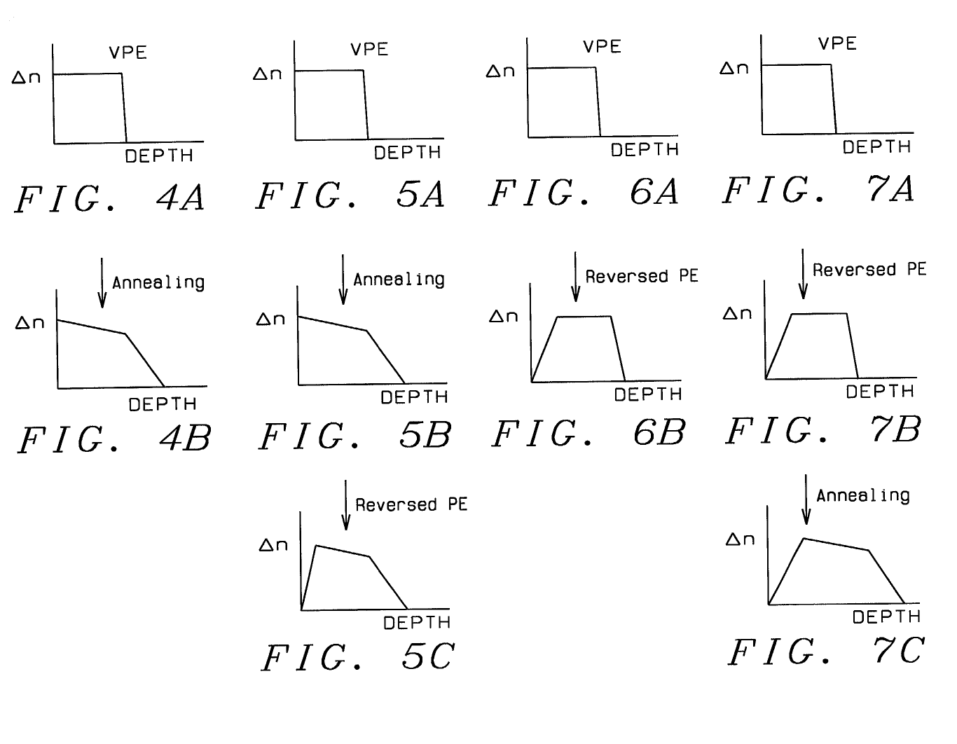

However, A-VPE (VPE+annealing) (as shown in FIG. 4) offers simplicity due to reduce process step and R-VPE (VPE+RPE) (as shown in FIG. 6) offers very high index step with buried structures. [One may also view the FIG. 4 A-VPE and FIG. 6 R-VPE as the degenerate/simplified versions of the FIG. 5 RA-VPE and the FIG. 7 AR-VPE, respectively.] Because it is not always possible to achieve a particular preferred index profile by a single approach, the above combinations offer a complete method to fabricate high-quality waveguide and simultaneously provide design flexibility.

Step Common to Each Embodiment

In each embodiment (FIGS. 4 through 7 ), the vapor phase proton is first diffused into the ferroelectric crystal material such as LiNbO₃ (lithium niobate) (step A) by a vapor proton-exchange (VPE) process to form a high-quality waveguide material structure (VPE) having a step refractive index profile as shown in FIG. 4A, FIG. 5A, FIG. 6A and FIG. 7A.

This VPE process may be performed in: 1) pure acid vapor such as, for example, benzoic acid, stearic acid or pyrophosphoric acid; 2) buffering acid vapor such as, for example, benzoic acid buffered with different lithium benzoate concentrations, or stearic acid buffered with different lithium stearate concentrations; to adjust the initial proton concentration and crystal phase before post annealing and/or reversed proton exchange for the specific embodiments of FIGS. 4 to 7.

The adjusted proton concentration is preferably from about 10²¹ to 2*10²² atoms/cm³ and is more preferably from about 2*10²¹ to 2*10²² atoms/cm³. The proton source is preferably benzoic acid or another chemical acid vapor containing hydrogen such as stearic acid or pyrophosphoric acid and is more preferably benzoic acid and its family.

The thermal anneal process of the First (FIG. 4), Second (FIG. 5) and Fourth (FIG. 7) Embodiments are identical.

The additional reverse proton-exchange processes of the Second (FIG. 5), Third (FIG. 6) and Fourth (FIG. 7) Embodiments also identical.

First Embodiment: Formation of A-VPE Waveguide—FIG. 4

As shown in FIG. 4 (the first embodiment) the waveguide material structure having a step refractive index profile as illustrated in FIG. 4A is post-thermally annealed to diffuse the proton formed by the VPE process into the LiNbO₃ to produce an A-VPE waveguide having a smoother refractive index profile as illustrated in FIG. 4B.

The first embodiment post-thermal anneal is conducted at the following conditions:

temperature: preferably from about 250 to 400° C. and more

preferably from about 300 to 360° C.; and

time: preferably from about 1 to 72 hours and more preferably from about 1 to 36 hours. with the optimized processing temperature and time will depend on the optimized design for specific applications.

FIGS. 8a and 8b illustrate a cross-sectional and perspective views, respectively, of the physical embodiment of the A-VPE channel waveguide of FIG. 4 showing substrate 100 (e.g. LiNbO₃), channel waveguide mask 102 (e.g. SiO₂) and A-VPE channel waveguide 104. Substrate 100 has poled microstructures, for example periodically poled LiNbO₃ as shown.

Second Embodiment: Formation of RA-VPE Waveguide—FIG. 5

As shown in FIG. 5 (the second embodiment) the waveguide material structure having a step refractive index profile as illustrated in FIG. 5A is post-thermally annealed to diffuse the proton formed by the VPE process into the LiNbO₃ to produce a waveguide having a smoother refractive index profile as illustrated in FIG. 5B.

The second embodiment post-thermal anneal is conducted at the same conditions as the A-VPE (FIG. 4) post-thermal anneal process.

Next, the waveguide is further optimized by an additional reverse proton-exchange process to form a buried waveguide and to shape the waveguide mode profile as illustrated in FIG. 5C.

The second embodiment additional reverse proton-exchange process is conducted at the following conditions:

Reverse proton chemical source is preferably performed in a mixture of LiNO₃—KNO₃—NaNO₃ by adjusting the composition ratio of the chemical mixtures, preferably with an LiNO₃ concentration of from about 30 to 45 mol. % and more preferably from about 35 to 40 mol. %;

preferably with a KNO₃ concentration of from about 30 to 60 mol. % and more preferably from about 40 to 50 mol. %; preferably with NaNO₃ concentration of from about 10 to 30 mol. % and more preferably from about 15 to 25 mol. %;

temperature: preferably from about 200 to 400° C. and more preferably from about 250 to 350° C.; and

time: preferably from about 1 to 72 hours and more preferably from about 1 to 36 hours with the optimized processing temperature and time depending upon the optimized waveguide design for specific applications.

FIGS. 8e and 8f illustrate a cross-sectional and perspective views, respectively, of the physical embodiment of the RA-VPE channel waveguide of FIG. 5 showing substrate 300 (e.g. LiNbO₃), channel waveguide mask 302 (e.g. SiO₂) and RA-VPE channel waveguide 304. Substrate 300 has poled microstructures, for example periodically poled LiNbO₃ as shown.

Third Embodiment: Formation of R-VPE Waveguide—FIG. 6

As shown in FIG. 6 (the third embodiment) the waveguide material structure having a step refractive index profile as illustrated in FIG. 6A is subjected to an additional reverse proton-exchange process to form a buried waveguide and to shape the waveguide mode profile as illustrated in FIG. 6B.

The third embodiment additional reverse proton-exchange process is conducted at the same conditions as the second embodiment RA-VPE (FIG. 5) reverse proton-exchange process with the optimized processing temperature and time depending upon the optimized waveguide design for specific applications.

FIGS. 8c and 8d illustrate a cross-sectional and perspective views, respectively, of the physical embodiment of the R-VPE channel waveguide of FIG. 6 showing substrate 200 (e.g. LiNbO₃), channel waveguide mask 202 (e.g. SiO₂) and R-VPE channel waveguide 204. Substrate 200 has poled microstructures, for example periodically poled LiNbO₃ as shown.

Fourth Embodiment: Formation of AR-VPE Waveguide—FIG. 7

As shown in FIG. 7 (the fourth embodiment) the waveguide material structure having a step refractive index profile as illustrated in FIG. 7A is subjected to an additional reverse proton-exchange process to form a buried waveguide and to shape the waveguide mode profile as illustrated in FIG. 7B.

The fourth embodiment additional reverse proton-exchange process is conducted at the same conditions as the second RA-VPE (FIG. 5) and third R-VPE (FIG. 6) reverse proton-exchange processes with the optimized processing temperature and time depending upon the optimized waveguide design for specific applications.

Next, the waveguide is further optimized by a post-thermal anneal to diffuse the proton formed by the VPE process into the LiNbO₃ to produce an AR-VPE waveguide having a smoother refractive index profile as illustrated in FIG. 5C.

The fourth embodiment post-thermal anneal is conducted at the same conditions as the first embodiment A-VPE (FIG. 4) and second embodiment RA-VPE (FIG. 5) post thermal anneal processes with optimized processing temperature and time will depending upon the optimized waveguide design for specific applications.

FIGS. 8e and 8f illustrate a cross-sectional and perspective views, respectively, of the physical embodiment of the AR-VPE channel waveguide of FIG. 7 showing substrate 300 (e.g. LiNbO₃), channel waveguide mask 302 (e.g. SiO₂) and RA-VPE channel waveguide 304. Substrate 300 has poled microstructures, for example periodically poled LiNbO₃ as shown. (It is noted that FIGS. 8e and 8f illustrates both the AR-VPE and RA-VPE channel waveguides of FIGS. 5 and 7.)

Such A-VPE (FIG. 4), RA-VPE (FIG. 5), R-VPE (FIG. 6) and AR-VPE (FIG. 7) processes not only allow the production of high quality waveguides, but also provides a full degree of design flexibility for device optimization. For example, a high quality, smoother refractive index profile can be formed by A-VPE, which provides an extra degree of freedom to adjust the high-quality, high step index profile waveguides as produced by VPE process. A high quality, buried waveguide can be obtained by R-VPE process, which allows maintain a high index step profile produced by VPE process and also form a more symmetric structure in depth direction. A high quality, symmetric and buried waveguide with smoother index profile can be obtained by RA-VPE and/or AR-VPE processes. RA-VPE process allows independent adjustment of VPE profile first through thermal annealing and then performs reversed proton exchange process to form a desired structure. While AR-VPE process allows simultaneously tailoring waveguide profile and then generates a more symmetric waveguide structure.

Thus above process allows flexible waveguide profile optimization for a wide variety of applications. Example applications are nonlinear frequency conversion such as blue light generation and telecommunication optical frequency mixers in high-quality, symmetric buried waveguide fabricated in ferroelectric nonlinear materials. The device optimization requires maximizing the integral overlapping of optical mode profiles at several different wavelengths and nonlinear materials. In addition, it also requires operating at preferred crystal phase to reduce the propagation loss. The fabrication process described in this invention will allow achieving the low loss and high-nonlinearity devices, and also simultaneously allows designing waveguide geometry to maximize the overall device efficiency by adjusting the optical mode profiles through the flexible fabrication steps.

Furthermore, mass production with a full wafer process could also be carried out using the embodiments of the present invention. The processes of the present invention can also be used for efficiency and fabrication optimization, and to produce a particular design such as noncritical structure design.

The embodiments of the present invention may be used in the following process applications:

1) quasi-phase matching waveguides and nonlinear guided wave applications such as: second harmonic generation; sum frequency generator difference frequency generation; wavelength converters; dispersion compensation elements; nonlinear compensation elements; optical parametric frequency amplification and generation; cascaded nonlinear frequency conversion; light source for laser display, laser scanner, laser printing, laser spectroscopic, sensing and detection; optical frequency mixers for optical fiber communication and optical signal processing etc.;

2) electro-optics applications and their optimizations such as electro-optics amplitude, phase modulators or high-speed modulators (see FIGS. 9a and 9b);

3) acoustic optics applications and optimization; and

4) integrated optics and waveguide coupling optimization.

Advantages of the Present Invention

The advantages of one or more embodiments of the present invention include:

1. high quality waveguide and process optimization: producing high index, symmetric, buried waveguides with lower propagation loss but also preserving material optical properties, such as nonlinear coefficients and electro-optic coefficients;

2. design flexibility for application optimization: the process steps offer high degree of freedoms for design optimization to a variety of applications;

3. only a few key process steps (i.e. VPE, RPE, Thermal annealing) are needed to develop and optimize. With a combination of above optimized process steps, a highly degree of freedom in fabrication process and design can be achieved. Thus, a sophisticated fabrication and design method can be offered only through three key process steps;

4. ease of further optimization and produce novel devices: Based on those three key optimized process steps, additional process and design combination can be easily developed. Examples are implementation of several sequential R-VPE, RA-VPE or AR-VPE processes to generate multi-layer waveguide structures for specific applications, such as fabrication of dispersion shifting waveguides, dispersion flattened waveguides efficiency enhancement for quasi-phase matching waveguides, nonlinear guided wave applications and integrated optics and waveguide optimization applications; an analogy to this type of design and devices is those used in optical fiber design and fabrication of dispersion shifting fiber or dispersion flattened fiber; and

5. two dimensional noncritical waveguide structures. As the method offers design and process flexibility, it can be used to generate a waveguide designs with optimized waveguide width and depth profiles simultaneously. Waveguide with such a design will have very stable properties and have a very high process tolerance, i.e. less sensitive to process condition, such as channel width variation, process temperature uniformity, and temperature stability etc.

While particular embodiments of the present invention have been illustrated and described, it is not intended to limit the invention, except as defined by the following claims.

We claim:

1. A method of fabricating a waveguide in ferroelectric crystals, comprising the steps of:
providing a ferroelectric crystal;
diffusing a vapor phase proton into the ferroelectric crystal by a vapor proton-exchange process to form a vapor proton-exchange (VPE) waveguide material structure having a step refractive index profile; and
treating the VPE waveguide material structure with one or more processes selected from the group consisting of: a post thermal anneal process and an additional reverse proton-exchange process to complete fabrication of the waveguide,
whereby the refractive index profile of the fabricated waveguide can be flexibly optimized.

2. The method of claim 1, wherein the ferroelectric crystal is selected from the group consisting of: lithium niobate (LiNbO₃), lithium tantalate (LiTaO₃), KTiOPO₄ (KTP), KNbO3,KDP and their family such as MgO:LiNbO₃, ZnO:LiNbO₃, periodically poled KTP (PP-KTP) periodically poled lithium niobate (PP-LN) or periodically poled lithium tantalate (PP-LT).

3. The method of claim 1, wherein the ferroelectric crystal is selected from the group consisting of: congruent LiNbO₃ (CLN) and stoichiometric LiNbO₃ (SLN); the above crystals with doping such as MgO:CLN, ZnO:CLN, MgO:SLN, ZnO:SLN; the above crystals at different crystal orientations including X-cut, Y-cut or Z-cut; and the above crystals with periodic or aperiodic ferroelectric domain reversals in their crystal bodies.

4. The method of claim 1, wherein the ferroelectric crystal is a LiNbO₃ or a LiTaO₃ ferroelectric crystal and their respective families.

5. The method of claim 1, wherein the ferroelectric crystal is a LiNbO₃ ferroelectric crystal and its family.

6. The method of claim 1, wherein the ferroelectric crystal has a crystal orientation selected from the group consisting of: X-cut, Y-cut or Z-cut.

7. The method of claim 1, wherein the vapor proton-exchange process is conducted in a vapor selected from the group consisting of: pure acid vapor and buffering/dilute acid vapor.

8. The method of claim 1, wherein the vapor proton-exchange process is conducted in a vapor selected from the group consisting of: pure benzoic acid vapor; pure stearic acid vapor; and pure pyrophosphoric acid vapor.

9. The method of claim 1, wherein the vapor proton-exchange (VPE) waveguide material structure has an adjusted proton concentration of from about 10²¹ to 2*10²² atoms/cm³,

10. The method of claim 1, wherein the vapor proton-exchange (VPE) waveguide material structure has an adjusted proton concentration of from about 2*10²¹ to 2*10²² atoms/cm³.

11. The method of claim 1, wherein the vapor phase proton has a source selected from the group consisting of benzoic acid, stearic acid, and pyrophosphoric acid.

12. The method of claim 1, wherein the vapor phase proton is benzoic acid and its family.

13. The method of claim 1, wherein the post thermal anneal process is conducted at the following conditions:
temperature: from about 250 to 400° C.; and
time: from about 1 to 72 hours.

14. The method of claim 1, wherein the post thermal anneal process is conducted at the following conditions:
temperature: from about 300 to 360° C.; and
time: from about 1 to 36 hours.

15. The method of claim 1, wherein the additional reverse proton-exchange process is conducted in a mixture of LiNO₃—KNO₃—NaNO₃ at a temperature of from about 200 to 400° C. for from about 1 to 72 hours; wherein the LiNO₃ concentration is from about 30 to 45 mol. %, the KNO₃ concentration is from about 30 to 60 mol. % and the NaNO₃ concentration is from about 10 to 30 mol. %.

16. The method of claim 1, wherein the additional reverse proton-exchange process is conducted in a mixture of LiNO₃—KNO₃—NaNO₃ at a temperature of from about 200 to 400° C. for from about 1 to 36 hours; wherein the LiNO₃ concentration is from about 35 to 40 mol. %, the KNO₃ concentration is from about 40 to 50 mol. % and the NaNO₃ concentration is from about 15 to 25 mol. %.

17. The method of claim 1, wherein the fabricated waveguide may be used in the following process applications:
quasi-phase matching waveguides and nonlinear guided wave applications such as: second harmonic generation; sum frequency generator difference frequency generation; wavelength converters; dispersion compensation elements; nonlinear compensation elements; optical parametric frequency amplification and generation; cascaded nonlinear frequency conversion; light source for laser display, laser scanner, laser printing, laser spectroscopic, sensing and detection; optical frequency mixers for optical fiber communication and optical signal processing;
electro-optics applications and their optimizations such as electro-optics amplitude, phase modulators or high-speed modulators;
acoustic optics applications and optimization; and
integrated optics and waveguide coupling optimization.

18. The method of claim 1, wherein the VPE waveguide material structure is treated with only a post thermal anneal process.

19. The method of claim 1, wherein the VPE waveguide material structure is treated with a post thermal anneal process and then an additional reverse proton-exchange process.

20. The method of claim 1, wherein the VPE waveguide material structure is treated only with an additional reverse proton-exchange process.

21. The method of claim 1, wherein the VPE waveguide material structure is treated with an additional reverse proton-exchange process and then a post thermal anneal process.

22. The method of claim 1, wherein the fabricated waveguide is a multi-layer waveguide structure formed by treating the VPE waveguide with a reverse proton-exchange process and then with at least one more additional sets of:
a) vapor phase proton exchange process followed by a further
b) reverse proton-exchange process.

23. The method of claim 1, wherein the fabricated waveguide is treated with one or more of the following sequence of processes:
a post thermal anneal process;
a post thermal anneal process followed by an additional reverse proton-exchange process;
an additional reverse proton-exchange process; and
an additional reverse proton-exchange process followed by a post thermal anneal process.

24. The method of claim 1, wherein the fabricated waveguide is a dispersion shifting waveguide.

25. The method of claim 1, wherein the fabricated waveguide is a dispersion flattened waveguide.

26. The method of claim 1, wherein the fabricated waveguide is simultaneously formed with an optimized waveguide width and depth profile.

27. The method of claim 1, wherein the fabricated waveguide is simultaneously formed with an optimized waveguide width and depth profile wherein the fabricated waveguide has a very high process tolerance.

28. The method of claim 1, wherein the fabricated waveguide is simultaneously formed with an optimized waveguide width and depth profile wherein the fabricated waveguide is less sensitive to: channel width variations; process temperature uniformity and temperature stability.

29. The method of claim 1, wherein the fabricated waveguide may be used in the following process applications:
dispersion shifting waveguides, dispersion flattened waveguides, efficiency enhancement for quasi-phase matching waveguides, nonlinear guided wave applications, integrated optics and waveguide optimization applications.

30. A method of fabricating a waveguide in ferroelectric crystals, comprising the steps of:
providing a ferroelectric crystal;
diffusing a vapor phase proton into the ferroelectric crystal by a vapor proton-exchange process to form a vapor proton-exchange (VPE) waveguide material structure having a step refractive index profile; and
treating the VPE waveguide material structure with a post thermal anneal to complete fabrication of the waveguide,
whereby the refractive index profile of the fabricated waveguide can be flexibly optimized.

31. The method of claim 30, wherein the ferroelectric crystal is selected from the group consisting of: lithium niobate (LiNbO₃), lithium tantalate (LiTaO₃), KTiOPO₄ (KTP), KNbO3,KDP and their family such as MgO:LiNbO₃, ZnO:LiNbO₃, periodically poled KTP (PP-KTP) periodically poled lithium niobate (PP-LN) or periodically poled lithium tantalate (PP-LT).

32. The method of claim 30, wherein the vapor proton-exchange process is conducted in a vapor selected from the group consisting of: pure acid vapor and buffering/dilute acid vapor.

33. The method of claim 30, wherein the vapor proton-exchange (VPE) waveguide material structure has an adjusted proton concentration of from about 10²¹ to 2*10²² atoms/cm³.

34. The method of claim 30, wherein the vapor proton-exchange (VPE) waveguide material structure has an adjusted proton concentration of from about 2*10²¹ to 2*10²² atoms/cm³.

35. The method of claim 30, wherein the vapor phase proton is benzoic acid and its family.

36. The method of claim 30, wherein the post thermal anneal process is conducted at the following conditions:
temperature: from about 250 to 400° C.; and
time: from about 1 to 72 hours.

37. The method of claim 30, wherein the post thermal anneal process is conducted at the following conditions:
temperature: from about 300 to 360° C.; and
time: from about 1 to 36 hours.

38. A method of fabricating a waveguide in ferroelectric crystals, comprising the steps of:
providing a ferroelectric crystal;
diffusing a vapor phase proton into the ferroelectric crystal by a vapor proton-exchange process to form a vapor proton-exchange (VPE) waveguide material structure having a step refractive index profile; and
treating the VPE waveguide material structure with a post thermal anneal and then an additional reverse proton-exchange process to complete fabrication of the waveguide,
whereby the refractive index profile of the fabricated waveguide can be flexibly optimized.

39. The method of claim 38, wherein the ferroelectric crystal is selected from the group consisting of: lithium niobate (LiNbO₃), lithium tantalate (LiTaO₃), KTiOPO₄ (KTP), KNbO3,KDP and their family such as MgO:LiNbO₃, ZnO:LiNbO₃, periodically poled KTP (PP-KTP) periodically poled lithium niobate (PP-LN) or periodically poled lithium tantalate (PP-LT).

40. The method of claim 38, wherein the vapor proton-exchange process is conducted in a vapor selected from the group consisting of: pure acid vapor and buffering/dilute acid vapor.

41. The method of claim 38, wherein the vapor proton-exchange (VPE) waveguide material structure has an adjusted proton concentration of from about 10²¹ to 2*10²² atoms/cm³.

42. The method of claim 38, wherein the vapor proton-exchange (VPE) waveguide material structure has an adjusted proton concentration of from about 2*10²¹ to 2*10²² atoms/cm³.

43. The method of claim 38, wherein the vapor phase proton is benzoic acid and its family.

44. The method of claim 38, wherein the post thermal anneal process conducted at the following conditions:
temperature: from about 250 to 400° C.; and
time: from about 1 to 72 hours; and the additional reverse proton-exchange process conducted in a mixture of LiNO₃—KNO₃—NaNO₃ at a temperature of from about 200 to 400° C. for from about 1 to 72 hours; wherein the LiNO₃ concentration is from about 30 to 45 mol. %, the KNO₃ concentration is from about 30 to 60 mol. % and the NaNO₃ concentration is from about 10 to 30 mol. %.

45. The method of claim 38, wherein the post thermal anneal process conducted at the following conditions:
temperature: from about 300 to 360° C.; and
time: from about 1 to 36 hours; and
the additional reverse proton-exchange process conducted in a mixture of LiNO₃—KNO₃—NaNO₃ at a temperature of from about 200 to 400° C. for from about 1 to 36 hours; wherein the LiNO₃ concentration is from about 35 to 40 mol. %, the KNO₃ concentration is from about 40 to 50 mol. % and the NaNO₃ concentration is from about 15 to 25 mol. %.

46. A method of fabricating a waveguide in ferroelectric crystals, comprising the steps of:
providing a ferroelectric crystal;
diffusing a vapor phase proton into the ferroelectric crystal by a vapor proton-exchange process to form a vapor proton-exchange (VPE) waveguide material structure having a step refractive index profile; and
treating the VPE waveguide material structure with only an additional reverse proton-exchange process to complete fabrication of the waveguide,
whereby the refractive index profile of the fabricated waveguide can be flexibly optimized.

47. The method of claim 46, wherein the ferroelectric crystal is selected from the group consisting of: lithium niobate (LiNbO₃), lithium tantalate (LiTaO₃), KTiOPO₄ (KTP), KNbO3,KDP and their family such as MgO:LiNbO₃, ZnO:LiNbO₃, periodically poled KTP (PP-KTP) periodically poled lithium niobate (PP-LN) or periodically poled lithium tantalate (PP-LT).

48. The method of claim 46, wherein the vapor proton-exchange process is conducted in a vapor selected from the group consisting of: pure acid vapor and buffering/dilute acid vapor.

49. The method of claim 46, wherein the vapor proton-exchange (VPE) waveguide material structure has an adjusted proton concentration of from about 10²¹ to 2*10²² atoms/cm³.

50. The method of claim 46, wherein the vapor proton-exchange (VPE) waveguide material structure has an adjusted proton concentration of from about 2*10²¹ to 2*10²² atoms/cm³.

51. The method of claim 46, wherein the vapor phase proton benzoic acid and its family.

52. The method of claim 46, wherein the additional reverse proton-exchange process conducted in a mixture of LiNO₃—KNO₃—NaNO₃ at a temperature of from about 200 to 400° C. for from about 1 to 72 hours; wherein the LiNO₃ concentration is from about 30 to 45 mol. %, the KNO₃ concentration is from about 30 to 60 mol. % and the NaNO₃ concentration is from about 10 to 30 mol. %.

53. The method of claim 46, wherein the additional reverse proton-exchange process conducted in a mixture of LiNO₃—KNO₃—NaNO₃ at a temperature of from about 200 to 400° C. for from about 1 to 36 hours; wherein the LiNO₃ concentration is from about 35 to 40 mol. %, the KNO₃ concentration is from about 40 to 50 mol. % and the NaNO₃ concentration is from about 15 to 25 mol. %.

54. A method of fabricating a waveguide in ferroelectric crystals, comprising the steps of:
providing a ferroelectric crystal;
diffusing a vapor phase proton into the ferroelectric crystal by a vapor proton-exchange process to form a vapor proton-exchange (VPE) waveguide material structure having a step refractive index profile; and
treating the VPE waveguide material structure with an additional reverse proton-exchange process and then a post thermal anneal to complete fabrication of the waveguide,
whereby the refractive index profile of the fabricated waveguide can be flexibly optimized.

55. The method of claim 54, wherein the ferroelectric crystal is selected from the group consisting of: lithium niobate (LiNbO₃), lithium tantalate (LiTaO₃), KTiOPO₄ (KTP), KNbO3,KDP and their family such as MgO:LiNbO₃, ZnO:LiNbO₃, periodically poled KTP (PP-KTP) periodically poled lithium niobate (PP-LN) or periodically poled lithium tantalate (PP-LT).

56. The method of claim 54, wherein the vapor proton-exchange process is conducted in a vapor selected from the group consisting of: pure acid vapor and buffering/dilute acid vapor.

57. The method of claim 54, wherein the vapor proton-exchange (VPE) waveguide material structure has an adjusted proton concentration of from about 10²¹ to 2*10²² atoms/cm³.

58. The method of claim 54, wherein the vapor proton-exchange (VPE) waveguide material structure has an adjusted proton concentration of from about 2*10²¹ to 2*10²² atoms/cm³.

59. The method of claim 54, wherein the vapor phase proton is benzoic acid and its family.

60. The method of claim 54, wherein the additional reverse proton-exchange process is conducted in a mixture of LiNO₃—KNO₃—NaNO₃ at a temperature of from about 200 to 400° C. for from about 1 to 72 hours; wherein the LiNO₃ concentration is from about 30 to 45 mol. %, the KNO₃ concentration is from about 30 to 60 mol. % and the NaNO₃ concentration is from about 10 to 30 mol. %; and the post thermal anneal process is conducted at the following conditions:
temperature: from about 250 to 400° C.; and
time: from about 1 to 72 hours.

61. The method of claim 54, wherein the additional reverse proton-exchange process is conducted in a mixture of LiNO₃—KNO₃—NaNO₃ at a temperature of from about 200 to 400° C. for from about 1 to 36 hours; wherein the LiNO₃ concentration is from about 35 to 40 mol. %, the KNO₃ concentration is from about 40 to 50 mol. % and the NaNO₃ concentration is from about 15 to 25 mol. %.; and the post thermal anneal process is conducted at the following conditions:
temperature: from about 300 to 360° C.; and
time: from about 1 to 36 hours.
